(19) United States
(12) Patent Application Publication
(10) Pub. No.: US 2017/0092492 A1
(43) Pub. Date: Mar. 30, 2017

(54) METHODS FOR FORMING A SILICON CONTAINING DIELECTRIC FILM USING A GAS MIXTURE WITH AR GAS DILUSION

(71) Applicant: Applied Materials, Inc., Santa Clara, CA (US)

(72) Inventors: Lai ZHAO, Campbell, CA (US); Gaku FURUTA, Sunnyvale, CA (US); Soo Young CHOI, Fremont, CA (US); Tae Kyung WON, San Jose, CA (US); Takao HASHIMOTO, Kobe-Shi (JP)

(21) Appl. No.: 14/879,050

(22) Filed: Oct. 8, 2015

Related U.S. Application Data
(60) Provisional application No. 62/233,984, filed on Sep. 28, 2015.

(51) Int. Cl. H01L 21/02; H01L 29/66

(52) U.S. Cl. CPC H01L 21/02274; H01L 21/02164; H01L 21/0217; H01L 21/0214; H01L 21/02208; H01L 29/6675

(57) ABSTRACT

Embodiments of the disclosure generally provide methods of forming a silicon containing layer utilizing a deposition gas mixture with Ar gas dilution in a plasma enhanced chemical vapor deposition (PECVD) process for display devices. The silicon containing layer may be used as an insulating layer, a passivation layer, a gate dielectric layer, an etch stop layer, an interlayer insulator or other suitable layers in thin film transistor (TFT) devices, or other suitable display applications. In one embodiment, a method for forming a silicon containing layer on a substrate includes supplying a gas mixture having a reacting gas, a TEOS gas and an argon gas into the processing chamber, wherein a ratio between the reacting gas and the argon gas is between about 10:1 and 1:60, and forming a silicon containing layer on the substrate

### CROSS-REFERENCE TO RELATED APPLICATIONS

This application claims benefit of U.S. Provisional Application Ser. No. 62/233,984 filed Sep. 28, 2015 (Attorney Docket No. APPM/23458L), which is incorporated by reference in its entirety.

### BACKGROUND

Field

Embodiments of the present invention generally relate to methods for forming a dielectric layer utilizing a gas mixture diluted with argon (Ar) gas. More particularly, embodiments of the invention relate to methods for forming a silicon containing dielectric layer utilizing a gas mixture diluted with argon (Ar) gas in a plasma enhanced chemical vapor deposition (PECVD) process.

Description of the Related Art

Display devices have been widely used for a wide range of electronic applications, such as TV, monitors, mobile phone, MP3 players, e-book readers, and personal digital assistants (PDAs) and the like. The display device is generally designed for producing desired image by applying an electric field to a liquid crystal that fills a gap between two substrates and has anisotropic dielectric constant that controls the intensity of the dielectric field. By adjusting the amount of light transmitted through the substrates, the light and image intensity, quality and power consumption may be efficiently controlled.

A variety of different display devices, such as active matrix liquid crystal display (AMLCD) or an active matrix organic light emitting diodes (AMOLED), may be employed as light sources for display devices which utilize touch screen panels. In the manufacturing of TFT devices, an electronic device with high electron mobility, low leakage current and high breakdown voltage, would allow more pixel area for light transmission and integration of circuitry, thereby resulting in a brighter display, higher overall electrical efficiency, faster response time and higher resolution displays. Low film qualities of the material layers formed in the device often result in poor device electrical performance and short service life of the devices. Thus, a stable and reliable method for forming film layers with high film qualities, such as high film density, low film leakage, and high breakdown voltage, for use in manufacturing electronic devices with lower threshold voltage shift and improved the overall performance of the electronic device are desired. In particular, the high film density of the film layers often have relatively low wet etching rate (WER) which indicates the dense film structure may provide robust film bonding architecture that may eliminate likelihood of film leakage for better electrical performance.

Therefore, there is a need for improved methods for forming high quality film layers for manufacturing TFT devices that produce improved device electrical performance and film stability.

### SUMMARY

Embodiments of the disclosure generally provide methods of forming a silicon containing layer utilizing a deposition gas mixture diluted with Ar gas in a plasma enhanced chemical vapor deposition (PECVD) process for display devices. The silicon containing layer may be used as an insulating layer, a passivation layer, a gate insulating layer, an etch stop layer, or other suitable layers in thin film transistor (TFT) devices, or other suitable display applications.

In one embodiment, a method for forming a silicon containing layer on a substrate includes supplying a gas mixture having a reacting gas, a TEOS gas and an argon gas into the processing chamber, wherein a ratio between the reacting gas and the argon gas is between about 10:1 and 1:30, and forming a silicon containing layer on the substrate in the presence of the gas mixture.

In another embodiment, a method for forming a silicon containing layer in a thin film transistor includes supplying a gas mixture comprising a TEOS gas, a O₂ gas and Ar gas into a plasma enhanced chemical vapor deposition chamber, wherein a ratio between the O₂ gas and the argon gas is between about 10:1 and 1:60, and forming a silicon containing layer on the substrate in the presence of the gas mixture.

In yet another embodiment, a method for forming a silicon containing layer in a thin film transistor includes supplying a gas mixture having a reacting gas, a TEOS gas and an argon gas into the processing chamber, wherein a ratio between the reacting gas and the argon gas is between about 10:1 and 1:30, and forming a silicon containing layer on the substrate in the presence of the gas mixture, wherein the silicon containing layer is an insulating layer, a passivation layer, a gate insulating layer, an etch stop layer in a thin film transistor device.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIG. 1 depicts a sectional view of the processing chamber that may be used to deposit a silicon containing layer in accordance with one embodiment of the present invention;

FIG. 2 depicts a process flow diagram of one embodiment of a method of forming a silicon containing layer that may be used in a TFT device structure;

FIG. 3A-3B depict different stages of manufacturing the silicon containing layer on a substrate of FIG. 2; and

FIG. 4 is a sectional view of one example of a thin film transistor device structure.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Embodiments of the disclosure generally provide methods of forming a silicon containing layer with enhanced film properties for display devices. The silicon containing layer may be used as an insulating layer, a passivation layer, a gate dielectric layer, an etch stop layer, or other suitable layers in TFT devices, OLED devices, LED devices, or other suitable display applications. In one example, the silicon containing layer may be formed by a deposition process utilizing a gas mixture that is diluted using Ar gas. The silicon containing layer formed by using the Ar gas diluted TEOS-based gas mixture provides high film qualities with low wet etching rate, high film density, desired film dielectric constant range (e.g., k value), thus efficiently enhancing the electrical performance of transistor and diode devices. It is noted that the silicon containing layer formed using the Ar gas diluted gas mixture may be used in other suitable devices other than the applications noted above.

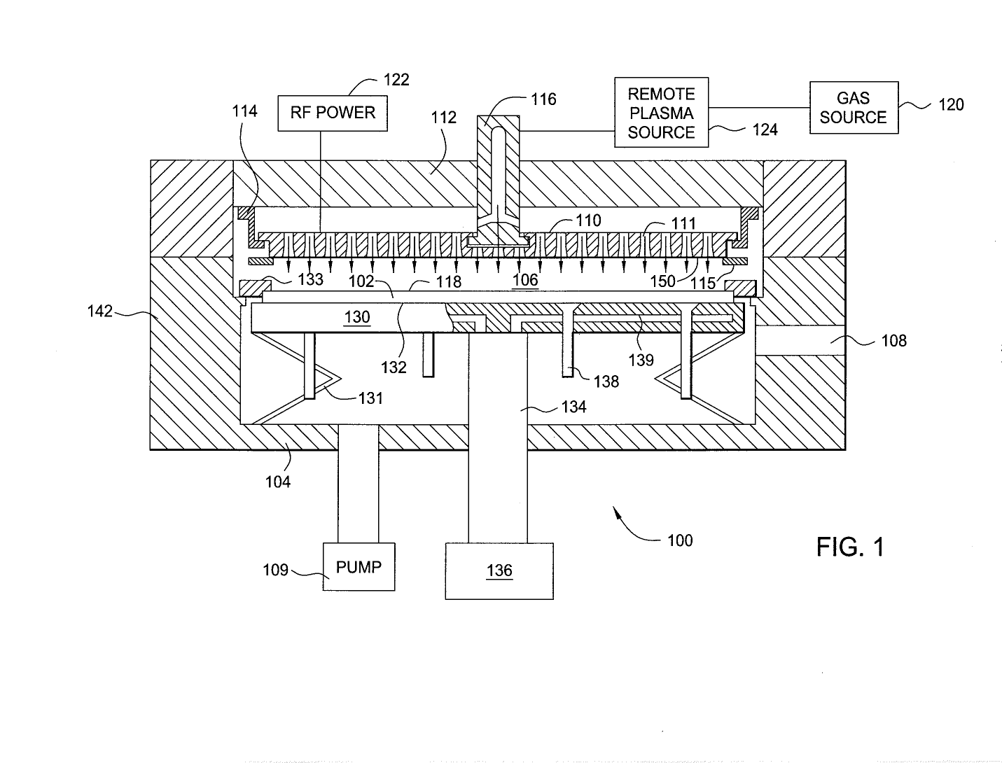

FIG. 1 is a schematic cross-section view of one embodiment of a plasma enhanced chemical vapor deposition (PECVD) chamber (processing chamber) 100 in which a silicon containing layer, such as a an insulating layer, a gate insulating layer, an etch stop layer, an interlayer insulator, or passivation layer in a TFT device structure, may be deposited. One suitable plasma enhanced chemical vapor deposition chamber is available from Applied Materials, Inc., located in Santa Clara, Calif. It is contemplated that other deposition chambers, including those from other manufacturers, may be utilized to practice the present disclosure.

The chamber 100 generally includes walls 142, a bottom 104 and a lid 112 which bound a process volume 106. A gas distribution plate 110 and substrate support assembly 130 which define a process volume 106. The process volume 106 is accessed through a valve 108 formed through the wall 142 such that a substrate 102 may be transferred in to and out of the chamber 100.

The substrate support assembly 130 includes a substrate receiving surface 132 for supporting the substrate 102 thereon. A stem 134 couples the substrate support assembly 130 to a lift system 136 which raises and lowers the substrate support assembly 130 between substrate transfer and processing positions. A shadow frame 133 may be optionally placed over periphery of the substrate 102 when processing to prevent deposition on the edge of the substrate 102. Lift pins 138 are moveably disposed through the substrate support assembly 130 and are adapted to space the substrate 102 from the substrate receiving surface 132. The substrate support assembly 130 may also include heating and/or cooling elements 139 utilized to maintain the substrate support assembly 130 at a desired temperature. The substrate support assembly 130 may also include grounding straps 131 to provide an RF return path around the periphery of the substrate support assembly 130.

The gas distribution plate 110 is coupled at its periphery to a lid 112 or wall 142 of the chamber 100 by a suspension 114. The gas distribution plate 110 may also be coupled to the lid 112 by one or more center supports 116 to help prevent sag and/or control the straightness/curvature of the gas distribution plate 110. In one embodiment, the gas distribution plate 110 may have different configurations with different dimensions. In an exemplary embodiment, the gas distribution plate 110 has a quadrilateral plan shape. The gas distribution plate 110 has a downstream surface 150 having a plurality of apertures 111 formed therein facing an upper surface 118 of the substrate 102 disposed on the substrate support assembly 130. The apertures 111 may have different shape, numbers, densities, dimensions, and distributions across the gas distribution plate 110. In one embodiment, the diameter of the apertures 111 may be selected between about 0.01 inch and about 1 inch.

A gas source 120 is coupled to the lid 112 to provide gas through the lid 112, and then through the apertures 111 formed in the gas distribution plate 110 to the process volume 106. A vacuum pump 109 is coupled to the chamber 100 to maintain the gas in the process volume 106 at a desired pressure.

An RF power source 122 is coupled to the lid 112 and/or to the gas distribution plate 110 to provide a RF power that creates an electric field between the gas distribution plate 110 and the substrate support assembly 130 so that a plasma may be generated from the gases present between the gas distribution plate 110 and the substrate support assembly 130. The RF power may be applied at various RF frequencies. For example, RF power may be applied at a frequency between about 0.3 MHz and about 200 MHz. In one embodiment the RF power is provided at a frequency of 13.56 MHz.

In one embodiment, the edges of the downstream surface 150 of the gas distribution plate 110 may be curved so that a spacing gradient is defined between the edge and corners of the gas distribution plate 110 and substrate receiving surface 232 and, consequently, between the gas distribution plate 110 and the upper surface 118 of the substrate 102. The shape of the downstream surface 150 may be selected to meet specific process requirements. For example, the shape of the downstream surface 150 may be convex, planar, concave or other suitable shape. Therefore, the edge to corner spacing gradient may be utilized to tune the film property uniformity across the edge of the substrate, thereby correcting property non-uniformity in the corner of the substrate. Additionally, the edge to center spacing may also be controlled so that the film property distribution uniformity may be controlled between the edge and center of the substrate. In one embodiment, a concave curved edge of the gas distribution plate 110 may be used so the center portion of the edge of the gas distribution plate 110 is spaced farther from the upper surface 118 of the substrate 102 than the corners of the gas distribution plate 110. In another embodiment, a convex curved edge of the gas distribution plate 110 may be used so that the corners of the gas distribution plate 110 are spaced farther than the edges of the gas distribution plate 110 from the upper surface 118 of the substrate 102.

A remote plasma source 124, such as an inductively coupled remote plasma source, may also be coupled between the gas source and the gas distribution plate 110. Between processing substrates, a cleaning gas may be energized in the remote plasma source 124 to remotely provide plasma utilized to clean chamber components. The cleaning gas may be further excited by the RF power provided to the gas distribution plate 110 by the power source 222. Suitable cleaning gases include, but are not limited to, NF₃, F₂, and SF₆.

In one embodiment, the substrate 102 that may be processed in the chamber 100 may have a surface area of 10,000 cm² or more, such as 25,000 cm² or more, for example about 55,000 cm² or more. It is understood that after processing the substrate may be cut to form smaller other devices.

In one embodiment, the heating and/or cooling elements 139 may be set to provide a substrate support assembly temperature during deposition of about 600 degrees Celsius or less, for example between about 100 degrees Celsius and about 500 degrees Celsius, or between about 200 degrees Celsius and about 500 degrees Celsius, such as about 300 degrees Celsius and 500 degrees Celsius.

The nominal spacing during deposition between the upper surface 118 of the substrate 102 disposed on the substrate receiving surface 132 and the gas distribution plate 110 may generally vary between 400 mil and about 1,200 mil, such as between 400 mil and about 800 mil, or other distance across the gas distribution plate 110 to provide desired deposition results. In one exemplary embodiment wherein the gas distribution plate 110 has a concave downstream surface, the spacing between the center portion of the edge of the gas distribution plate 110 and the substrate receiving surface 132 is between about 400 mils and about 1400 mils and the spacing between the corners of the gas distribution plate 110 and the substrate receiving surface 132 is between about 300 mils and about 1200 mils.

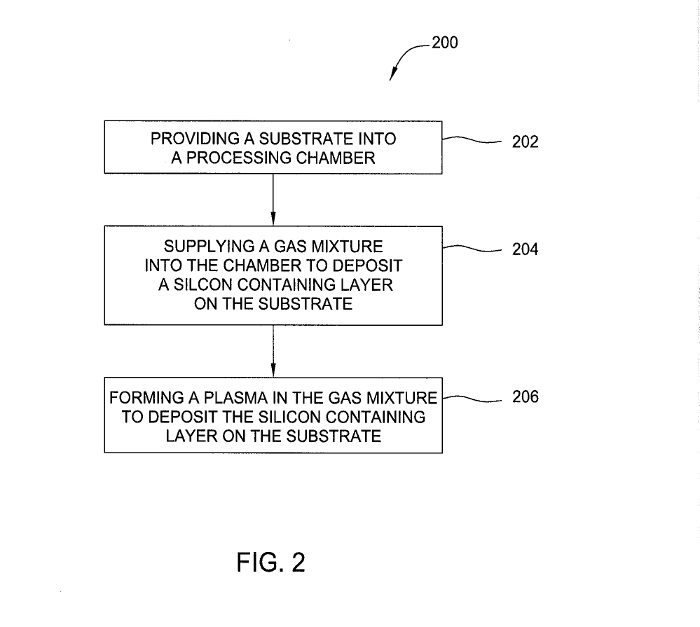

FIG. 2 depicts a flow diagram of one embodiment of a method 200 for forming a silicon containing layer suitable for use as an interlayer insulator, an insulating layer, a gate insulating layer, an etch stop layer, a passivation layer or any suitable interface layer disposed in a thin-film transistor device. The process may be practiced in the processing chamber 100, as described in FIG. 1, or other suitable processing chamber. The method 200 illustrates a method of forming a silicon containing layer using a gas mixture having a TEOS gas, an oxygen gas with argon gas dilution that may be suitable for using in TFT devices, or diode devices.

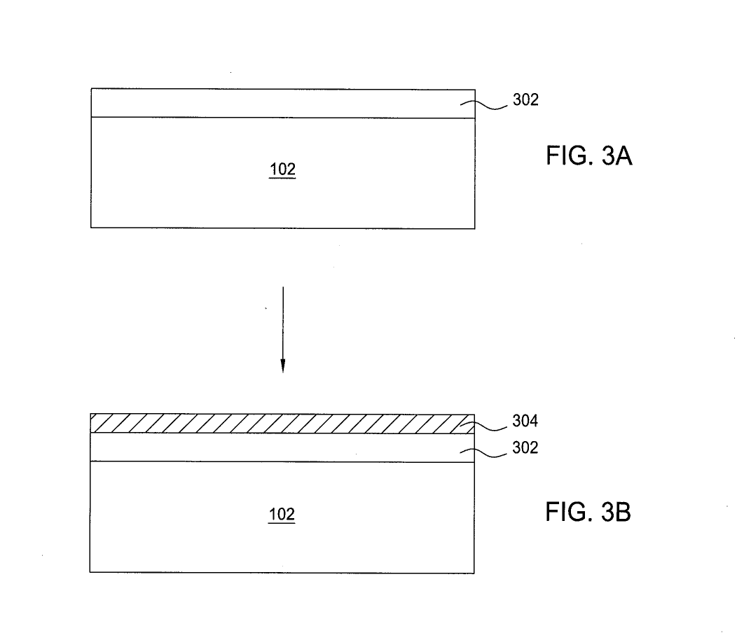

The method 200 begins at operation 202 by providing the substrate 102 in a process chamber, such as the processing chamber 100 depicted in FIG. 1. The method 200 may be utilized to form a silicon containing layer, which may be used to form an interlayer insulator, an insulating layer, a gate insulating layer, an etch stop layer or a passivation layer in a TFT device structure, which will be further described below with referenced to FIG. 5. It is noted that the substrate 102 may have different combination of films, structures or layers previously formed thereon to facilitate forming different device structures or different film stack on the substrate 102. In one example, the substrate 102 may have a film structure 302 formed thereon, as shown in FIG. 3A. The film structure 302 may include any suitable structures previously formed thereon to facilitate forming different device structures. The substrate 102 may be any one of glass substrate, plastic substrate, polymer substrate, metal substrate, singled substrate, roll-to-roll substrate, or other suitable transparent substrate suitable for forming a thin film transistor thereon.

At operation 204, a gas mixture is supplied into the processing chamber to deposit a silicon containing layer 304 on the substrate 102, as depicted in FIG. 3B. The gas mixture comprises at least a silicon-based gas, a reacting gas and an inert gas, such as Ar gas. The silicon-based gas is used as a silicon source precursor to provide silicon atoms for forming the silicon containing layer 304 on the substrate 102. Suitable examples of the silicon-based gas include silane (SiH₄), disilane (Si₂H₆), silicon tetrafluoride (SiF₄), tetraethyl orthosilicate (TEOS), silicon tetrachloride (SiCl₄), dichlorosilane (SiH₂Cl₂), and combinations thereof. In one example, the silicon-based gas is tetraethyl orthosilicate (TEOS) gas.

Furthermore, a reacting gas is supplied in the gas mixture to react with the silicon-based gas to form the desired silicon containing layer 304 on the substrate 102. In the embodiment wherein the silicon containing layer 304 is desired to be a silicon oxide layer (SiO₂), the reacting gas is an oxygen containing gas to provide oxygen source to react with the silicon-based gas for forming the silicon oxide layer. Suitable examples of the oxygen containing gas include O₂, N₂O, NO₂, O₃, CO, CO₂, and the like. In the embodiment wherein a silicon nitride layer (SiN) is desired, the reacting gas is a nitrogen containing gas to provide nitrogen source for forming the silicon nitride layer. Suitable examples of the nitrogen containing gas include NH₃, N₂, and the like. In the embodiment wherein a silicon oxynitride (SiON) layer is desired, the reacting gas may be an oxygen and nitrogen containing gas to provide nitrogen and oxygen source for forming the silicon oxynitride layer. Suitable examples of the oxygen and nitrogen containing gas for forming silicon oxynitride include O₂, N₂O, NO₂, NH₃, N₂, O₃, CO, CO₂, combinations thereof, and the like. In one embodiment, the oxygen and nitrogen containing gas for forming silicon oxynitride includes N₂O, NO₂, or combination of O₂ and NH₃ gas or combination of O₂ and N₂ gas.

The silicon-based gas, reacting gas and inert gas are supplied at a predetermined gas flow ratio. Particularly, the predetermined gas flow ratio of inert gas to reacting gas assists deposition of the silicon containing layer 304 with desired film properties, such as high film density, low film wet etching rate (WER), high film breakdown voltage and the like. In one particular example described here, the silicon-based gas is TEOS gas, the reacting gas is O₂ gas and the inert gas is Ar gas. In one example, the TEOS gas, O₂ gas and Ar gas are supplied into the processing chamber at a predetermined ratio.

Specifically, in one example, the volumetric ratio of O₂ gas to Ar gas supplied in the gas mixture is between about 30:1 and about 1:60, for example between about 10:1 and about 1:60, such as between about 10:1 and about 1:10, for example about 1:5 and about 5:1, such as about 1:2. In one example, the volumetric ratio of the Ar gas to the O₂ gas (e.g., Ar:O₂) may be greater than 5:1, such as between 7:1 and 8:1. Alternatively, the volumetric ratio (R) of the argon gas to the O₂ gas is controlled between about 10 and 0.1 (Ar/O₂), such as between about 7 to 2.

As Ar atoms have a lower activation energy, Ar atoms may be easily activated during a plasma process, thus, efficiently increasing plasma density during process. Increased plasma density may provide higher ions/radical density while forming the silicon containing layer 304, thus increasing the resultant film quality of the silicon containing layer 304 as well.

In some embodiments, the silicon-based gas, e.g., the TEOS gas, and the O₂ gas may be supplied at a volumetric ratio between about 1:3 and about 1:30. Furthermore, the silicon-based gas, e.g., the TEOS gas, and the Ar gas may be supplied at a volumetric ratio between about 1:15 and about 1:30. Alternatively, a ratio between the combined oxygen and argon gas flow (O₂+Ar) and the TEOS gas is controlled at the range between 0.1:1 and 1:60. The argon dilution deposition process may also provide a good deposition rate, such as greater than 500 Å per minute, so as to maintain desired throughput of manufacture.

At operation 206, a RF source power is applied to the processing chamber 100 to form a plasma from the gas mixture to deposit the silicon containing layer 304, such as silicon oxide. The RF source power is applied to maintain the plasma during deposition. In one embodiment, the RF source power density may be supplied between about 20 mWatt/cm² and about 1000 mWatt/cm². The RF source power is provided between about 100 kHz and about 100 MHz, such as about 350 kHz or about 13.56 MHz. Optionally, a RF bias power may also be supplied during the deposition process as needed.

Furthermore, several process parameters may also be controlled during deposition. The spacing of the substrate to the gas distribution plate assembly may be controlled in accordance with the substrate dimension. In one embodiment, the processing spacing for a substrate having a top surface area greater than 1 square meters is controlled between about 400 mils and about 1200 mils, for example, between about 400 mils and about 850 mils, such as 600 mils. The substrate temperature may be controlled at between about 100 degrees Celsius and about 500 degrees Celsius, such as at about 250 degrees Celsius. The process pressure is maintained at between about 0.1 Torr and about 3 Torr, such as about 0.68 Torr.

In one embodiment, the high argon dilution in the gas mixture along with a relatively high RF power, such as greater than about 250 milliWatts, in the processing chamber assists dissociation of a high number of atomic silicon and oxygen in the gas mixture, thereby providing a strong silicon-silicon and silicon-oxygen in the silicon containing layer 304.

In one embodiment, the silicon containing layer 304, such as a silicon oxide layer, may have a refractive index (R.I.) between about 1.42 to 1.49 and a stress between about −1.0 E9d/cm² and about −5.0 E9d/cm², e.g., a compressive film structure. The dielectric constant (e.g., k value) may be between about 3.8 and about 4.2. The breakdown voltage may be between about 7.5 MV/cm and about 10.5 MV/cm. FTIR data also indicates that the silicon containing layer 304 includes a good Si—O bonding structure as desired. Thus, the enhanced silicon-silicon and silicon-oxygen bonding provides desired stronger or compatible mechanical properties, such as hardness, elastic modulus and density, thus also providing the resultant silicon containing layer 304 with high selectivity during the subsequent etching process, when utilizing as an etching stop layer. Thus, the silicon containing layer 304 with desired optical and mechanical properties may be controlled and obtained.

Thus, using a well-controlled volumetric gas ratio between silicon-based gas, oxygen gas and argon gas, (particularly oxygen gas and argon gas), film properties of the silicon containing layer 304, with desired film density along with film stress, break-down voltage, dielectric constant (e.g., k value) and film transparency (e.g., optical properties), may be advantageously obtained.

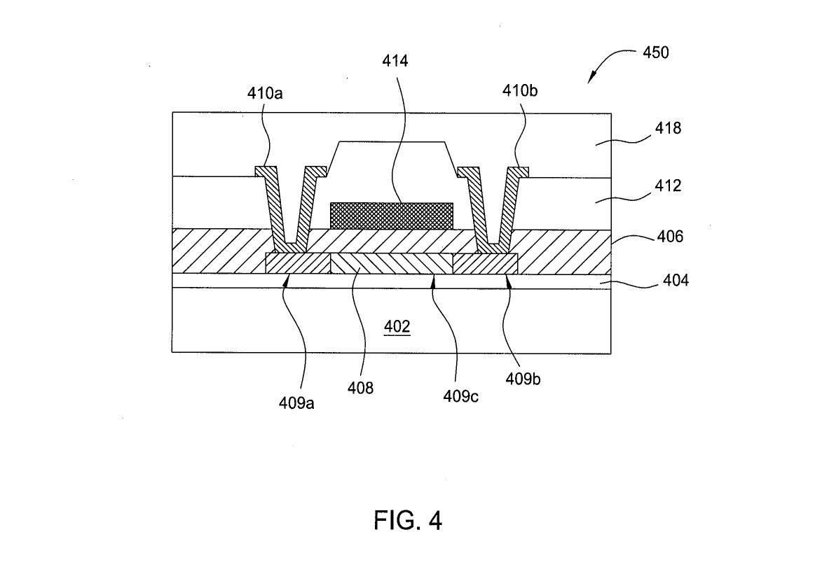

FIG. 4 depicts an example of a low temperature polysilicon (LTPS) TFT device 450 formed on a substrate 402. The substrate 402 may be similar to the substrate 102 described above. The LTPS TFT devices 450 are MOS devices built with a source region 409a, channel region 408, and drain region 409b formed on the optically transparent substrate 402 with or without an optional insulating layer 404 disposed thereon. The source region 409a, channel region 408, and drain region 409b are generally formed from an initially deposited amorphous silicon (a-Si) layer that is typically later thermal or laser processed to form a polysilicon layer. The source, drain and channel regions 409a, 408, 409b can be formed by patterning areas on the optically transparent substrate 402 and ion doping the deposited initial a-Si layer, which is then thermally or laser processed (e.g., an Excimer Laser Annealing process) to form the polysilicon layer. A gate insulating layer 406 is then deposited on top of the deposited polysilicon layer(s) to isolate a gate electrode 414 from the channel 408, source 409a and drain regions 409b. The gate electrode 414 is formed on top of the gate insulating layer 406. The gate insulating layer 406 is also commonly known as a gate oxide layer since it is commonly made of a silicon dioxide (SiO₂) layer. An interlayer insulator 412 and device connections are then made through the insulating layer to allow control of the TFT devices.

After the interlayer insulator 412 is formed, a source-drain metal electrode layer 410a, 410b is then deposited, formed and patterned in the interlayer insulator 412. After the source-drain metal electrode layer 410a, 410b is patterned, a passivation layer 418 is then formed over the source-drain metal electrode layer 410a, 410b.

It is noted that the insulating layer 404, the gate insulating layer 406, the interlayer insulator 412 and the passivation layer 418 may be in form of a single layer or multiple layers as needed for different devices requirements and designs. Furthermore, the insulating layer 404, the gate insulating layer 406, the interlayer insulator 412 and the passivation layer 418 may also be formed from the silicon containing layer 304 described above utilizing the process 300 described in FIG. 3.

Thus, the methods described herein advantageously improve the electron stability, electrical performance, film uniformity, film density and film qualities of electric devices by controlling the film properties of the silicon containing layer, particularly a silicon oxide layer, formed in the device structure.

While the foregoing is directed to embodiments of the present invention, other and further embodiments of the invention may be devised without departing from the basic scope thereof, and the scope thereof is determined by the claims that follow.

1. A method for forming a silicon containing layer on a substrate comprising:
supplying a gas mixture having a reacting gas, a tetraethyl orthosilicate (TEOS) gas and an argon gas into a processing chamber, wherein a volumetric ratio of the reacting gas to the argon gas is between about 10:1 and 1:60, wherein the reacting gas is an oxygen containing gas; and
forming a silicon containing layer on the substrate in the presence of the gas mixture, wherein the silicon containing layer is utilized as a gate insulating layer, an etching stop layer, or a passivation layer in a thin film transistor device structure.

2. The method of claim 1, wherein the reacting gas is O₂.

3. The method of claim 2, wherein the silicon containing layer is a silicon oxide layer.

4. The method of claim 2, wherein the ratio of the argon gas to the O₂ gas supplied in the gas mixture is greater than 5.

5. The method of claim 2, wherein the volumetric ratio of the argon gas to the O₂ gas supplied in the gas mixture is between about 7:1 and 8:1.

6. The method of claim 1, wherein supplying the gas mixture further comprises:
maintaining a substrate temperature at between about 100 degrees Celsius and about 300 degrees Celsius.

7. The method of claim 1, further comprising:
applying a RF source power between about 20 mWatt/cm² and about 1000 mWatt/cm² to maintain a plasma formed from the gas mixture.

8. The method of claim 2, wherein a volumetric ratio of the combination of the O₂ gas and the argon gas to the TEOS gas is between about 0.1:1 and about 1:60.

9. (canceled)

10. The method of claim 1, wherein the thin film transistor device structure further includes a low temperature polysilicon structure.

11. The method of claim 1, wherein silicon containing layer has a deposition rate greater than 500 Å per minute.

12. The method of claim 1, wherein the silicon containing layer has a breakdown voltage between about 7.5 MV/cm and about 10.5 MV/cm.

13. The method of claim 1, wherein the silicon containing layer is a silicon nitride layer or a silicon oxynitride layer.

14. The method of claim 1, wherein a volumetric ratio between the TEOS gas and the reacting gas is controlled at between about 1:5 and about 1:30.

15. The method of claim 1, wherein a volumetric ratio between the TEOS gas and the argon gas is between about 1:15 and about 1:30.

16. A method for forming a silicon containing layer in a thin film transistor comprising:
supplying a gas mixture comprising a TEOS gas, a O₂ gas and Ar gas into a plasma enhanced chemical vapor deposition chamber, wherein a volumetric ratio of the O₂ gas to the argon gas is between about 10:1 and 1:10; and
forming a silicon containing layer on the substrate in the presence of the gas mixture, wherein the silicon containing layer is utilized as a gate insulating layer, an etching stop layer, or a passivation layer in a thin film transistor device structure.

17. (canceled)

18. The method of claim 16, wherein the volumetric ratio of the argon gas to the O₂ gas supplied in the gas mixture is between about 7:1 and 8:1.

19. The method of claim 16, wherein thin film transistor device structure further includes a low temperature polysilicon structure.

20. A method for forming a silicon containing layer in a thin film transistor comprising:
supplying a gas mixture having a oxygen containing gas, a TEOS gas and an argon gas into the processing chamber, wherein a volumetric ratio of the oxygen containing gas to the argon gas is between about 10:1 and 1:30 and a volumetric ratio of a combination of the oxygen containing gas and the argon gas to the TEOS gas is between about 0.1:1 and about 1:60; and
forming a silicon containing layer on the substrate in the presence of the gas mixture, wherein the silicon containing layer is an insulating layer, a passivation layer, a gate insulating layer, an interlayer insulator, an etch stop layer in a thin film transistor device.
